(19) United States
(12) Patent Application Publication
(10) Pub. No.: US 2018/0044776 A1
(43) Pub. Date: Feb. 15, 2018

(54) VACUUM DEPOSITION HEATING DEVICE

(71) Applicant: Shenzhen China Star Optoelectronics Technology Co., Ltd., Shenzhen City (CN)

(72) Inventors: Yang Liu, Shenzhen City (CN); Yawei Liu, Shenzhen City (CN)

(21) Appl. No.: 15/032,046

(22) PCT Filed: Feb. 26, 2016
(86) PCT No.: PCT/CN2016/074612

§ 371 Date: Apr. 25, 2016

(30) Foreign Application Priority Data
Jan. 29, 2016 (CN) 201610064564.0

(51) Int. Cl. C23C 14/26; C23C 14/54; C23C 14/24

(52) U.S. Cl. CPC C23C 14/26; C23C 14/243; C23C 14/54; H01L 51/56

(57) ABSTRACT

The present invention provides a vacuum deposition heating device, which includes a heating device outer wall (3), a crucible (1) disposed inside the heating device outer wall (3), and a crucible cover (2) positioned on the crucible (1). A primary heating coil (11) is arranged between the crucible (1) and the heating device outer wall (3) and corresponds to outer circumferences of the crucible (1) and the crucible cover (2). The crucible cover (2) has a center in which a jet opening (20) that extends through top and bottom surfaces of the crucible cover (2) is formed. The crucible cover (2) is provided thereon with a secondary heating coil (21) corresponding to an outer circumference of the jet opening (20). The primary heating coil (11) and the secondary heating coil (21) are electrically connected to a power supply and can be controlled individually and independently for heating, so as to effectively reduce a temperature difference in the crucible in a horizontal radial direction to prevent opening jamming and allow for expansion of diameter to thereby increase the amount of material applied, reduce the times of chamber opening, increase manufacturing efficiency. In addition, the structure is simple and the manufacture thereof is easy.

### BACKGROUND OF THE INVENTION

### 1. Field of the Invention

The present invention relates to the field of display technology, and in particular to a vacuum deposition heating device.

### 2. The Related Arts

Organic light-emitting diode (OLED) is regarded as the next generation of display technology and possesses excellent display performance, particularly being self-luminous, simple structure, ultrathin and ultra-light, fast response speed, wide view angle, low power consumption, and being capable of flexible displaying. Mass production techniques of OLED generally involve vacuum deposition for formation of films of OLED materials.

In a vacuum deposition process conducted in a vacuum deposition chamber, a material is placed in a crucible and the crucible is placed in a heating device to be heated to an evaporation temperature so as to vaporize the material such that the vaporized material molecule jets out of a jet opening of a crucible cover to get deposited on a substrate for formation of a solid state film. Improper control of temperature would cause a relatively low temperature in the crucible cover and vaporized material molecules would deposit on the crucible cover and gets expanded to eventually block (jam) the jet opening of the crucible. Partial jamming of the jet opening will cause inaccuracy of film thickness and thus affecting film quality and the performance of a final product. Full jamming of the jet opening would cause no formation of film and overheating of the material left in the crucible. For the OLED organic materials, overheating would make decomposition of the material, making it useless. Further, preventing opening jamming is the essential requirement for a vacuum deposition process and is also an essential condition for providing high quality films.

To prevent opening jamming and ensure stable vacuum deposition conditions, temperature distribution in two directions, including a vertical axial direction and a horizontal radial direction, of a crucible must be realized. They must meet the following to conditions:

(1) Vertical axial direction: temperature of an upper portion of the crucible must be higher than the temperature of a lower portion, meaning a temperature gradient from top to bottom must be present.

(2) Horizontal radial direction: a temperature difference between a peripheral portion and a central portion of the crucible must be as smaller as possible, meaning the temperature of the crucible must be as consistent as possible in a horizontal direction.

Referring to FIG. 1, a schematic cross-sectional view is given to illustrate a conventional vacuum deposition heating device, which comprises a heating device outer wall 300, a crucible 100 disposed inside the heating device outer wall 300, and a crucible cover 200 positioned on the crucible 100. The crucible cover 200 has a center in which a jet opening 201 is formed and extending through upper and lower surfaces of the crucible cover 200. A heating coil 110 is arranged between the crucible 100 and the heating device outer wall 300 to correspond to outer circumferences of the crucible 100 and the crucible cover 200, wherein the heating coil 110 has a portion that corresponds to an upper portion of the crucible 100 and has a relatively large distribution density than a distribution density of a portion of the heating coil 110 that corresponds to a lower portion of the crucible 100 so that the upper portion of the crucible is provided with a temperature that is greater than that provided to the lower portion of the crucible. This can effectively overcome the issue that the crucible must show a temperature difference in the vertical direction. However, since the heating coil 110 is arranged to surround the circumference of the crucible 100, there is also a temperature gradient from outer side to inner side in the horizontal direction. In other words, the temperature in the peripheral portion of the crucible 100 in a radial direction is greater than the temperature in the central portion. The temperature difference in the horizontal radial direction also result in the temperature around the jet opening 201 of the crucible cover being lower than the temperature around a crucible wall 120, and this would impose a great influence on OLED materials having poor thermal conductivity. Further, vaporized material molecules jet out of the jet opening 201 of the crucible cover is also a process of heat dissipation, and would result in a heat loss rate in the area of opening being greater than that of other portions of the crucible. Heretofore, no technical solution is dedicated to handle the issue of temperature difference in the horizontal radial direction and due to constraints imposed by the temperature difference in the horizontal radial direction, crucibles are prevented from expanding the diameters thereof for the larger the crucible diameter is, the greater the temperature difference would be in the radial direction, making the opening jammed more easily. This condition limits the amount of material that can be received in a crucible and is adverse in reducing the frequency of opening the chamber to change material and maintenance of the machine and thus opposite to the increase of manufacturing efficiency.

### SUMMARY OF THE INVENTION

An object of the present invention is to provide a vacuum deposition heating device, which effectively reduces temperature difference in a horizontal radial direction of a crucible, prevents opening from being jammed by material, and allows for expansion of diameter to increase the amount of material applied, reduce the times of opening chamber, and increase the manufacturing efficiency.

To achieve the above object, the present invention provides a vacuum deposition heating device, which comprises heating device outer wall, a crucible disposed inside the heating device outer wall, and a crucible cover positioned on the crucible;

a primary heating coil being arranged between the crucible and the heating device outer wall and corresponding to outer circumferences of the crucible and the crucible cover; the crucible cover having a center in which a jet opening that extends through top and bottom surfaces of the crucible cover is formed, the crucible cover being provided thereon with a secondary heating coil corresponding to an outer circumference of the jet opening; the primary heating coil and the secondary heating coil being electrically connected to a power supply and being independently controllable for heating.

The secondary heating coil is of a helical form, comprising a tailing end located at a terminal of an innermost turn and an electrode end located at a terminal of an outermost turn; the tailing end is positioned on the crucible cover; and the electrode end projects outside the crucible cover and partially extends downward in a vertical direction.

An electrical connector is arranged between the crucible and the heating device outer wall at a location corresponding to a lower tip of the electrode end; the electrode end is inserted into the electrical connector; and the electrical connector is electrically connected to a heating circuit.

The primary heating coil has a coil distribution density arranged in an upper portion of the crucible and greater than a coil distribution density arranged in a lower portion of the crucible.

In a vacuum deposition process, application of electricity to the primary heating coil and the secondary heating coil is controlled individually so as to have a temperature of the crucible cover higher than a temperature of the crucible.

The secondary heating coil is provided with a protective cover.

The protective cover is made of a metal.

The protective cover and the secondary heating coil are welded together; or alternatively, the protective cover is provided with a retention slot and the secondary heating coil is fit into and retained in the retention slot.

The crucible cover is provided with a first thermal couple at a location corresponding to an outer edge of the secondary heating coil to monitor a temperature of the crucible cover; and the crucible is provided with a second thermal couple at a location adjacent to a bottom thereof to monitor a temperature of the crucible.

The present invention also provides a vacuum deposition heating device, which comprises a heating device outer wall, a crucible disposed inside the heating device outer wall, and a crucible cover positioned on the crucible;

a primary heating coil being arranged between the crucible and the heating device outer wall and corresponding to outer circumferences of the crucible and the crucible cover; the crucible cover having a center in which a jet opening that extends through top and bottom surfaces of the crucible cover is formed, the crucible cover being provided thereon with a secondary heating coil corresponding to an outer circumference of the jet opening; the primary heating coil and the secondary heating coil being electrically connected to a power supply and being independently controllable for heating;

wherein the secondary heating coil is of a helical form, comprising a tailing end located at a terminal of an innermost turn and an electrode end located at a terminal of an outermost turn; the tailing end is positioned on the crucible cover; and the electrode end projects outside the crucible cover and partially extends downward in a vertical direction;

wherein the primary heating coil has a coil distribution density arranged in an upper portion of the crucible and greater than a coil distribution density arranged in a lower portion of the crucible;

wherein in a vacuum deposition process, application of electricity to the primary heating coil and the secondary heating coil is controlled individually so as to have a temperature of the crucible cover higher than a temperature of the crucible.

The efficacy of the present invention is that the present invention provides a vacuum deposition heating device, which comprises a primary heating coil arranged around circumferences of a crucible and a crucible cover and a secondary heating coil arranged on the crucible cover, wherein the primary heating coil and the secondary heating coil are controllable independently for heating so as to ensure a temperature from top to bottom present in the crucible and at the same time effectively reducing a temperature difference in the crucible in a horizontal radial direction to prevent opening jamming and allow for expansion of diameter to thereby increase the amount of material applied, reduce the times of chamber opening, increase manufacturing efficiency. In addition, the structure is simple and the manufacture thereof is easy.

### BRIEF DESCRIPTION OF THE DRAWINGS

For better understanding of the features and technical contents of the present invention, reference will be made to the following detailed description of the present invention and the attached drawings. However, the drawings are provided for the purposes of reference and illustration and are not intended to impose limitations to the present invention.

In the drawings:

FIG. 1 is a schematic cross-sectional view illustrating a conventional vacuum deposition heating device;

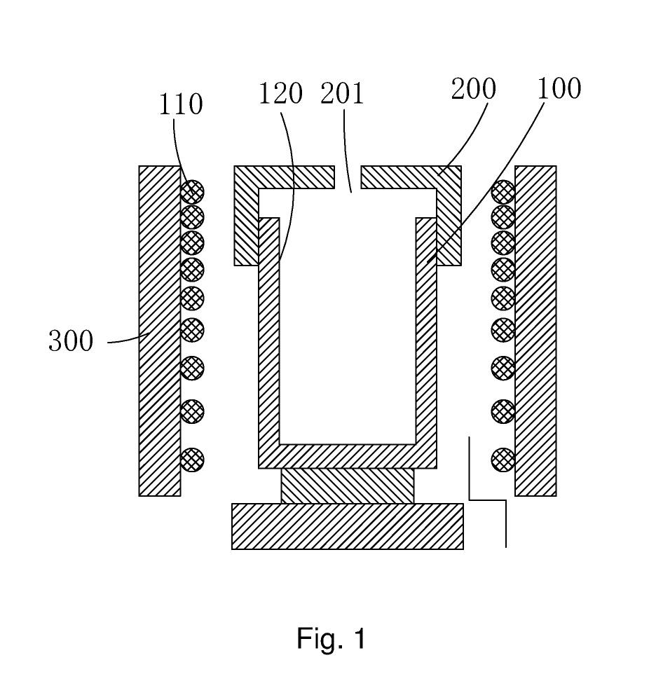

FIG. 2 is a schematic cross-sectional view illustrating a vacuum deposition heating device according to the present invention;

FIG. 3 is a schematic top plan view illustrating a secondary heating coil of the vacuum deposition heating device according to the present invention; and

FIG. 4 is a schematic top plan view illustrating a protective cover of the secondary heating coil of the vacuum deposition heating device according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

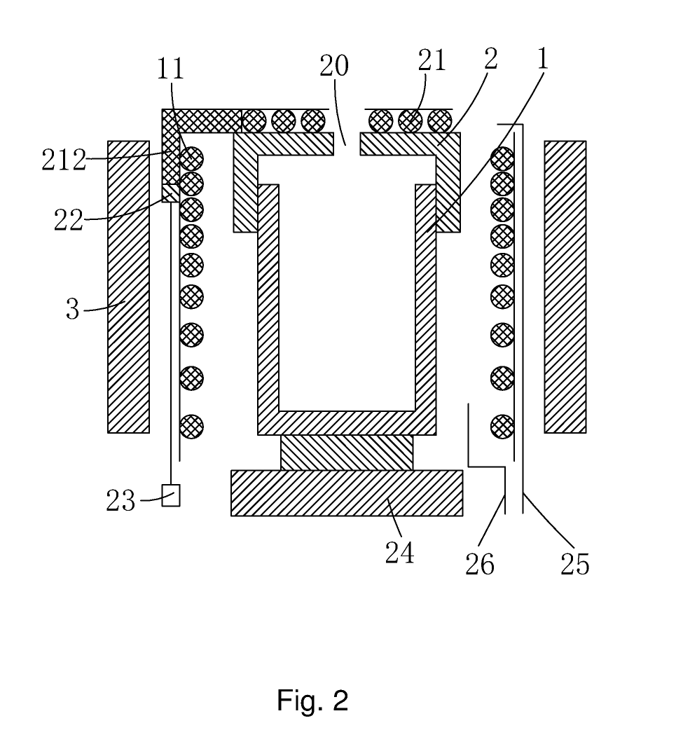

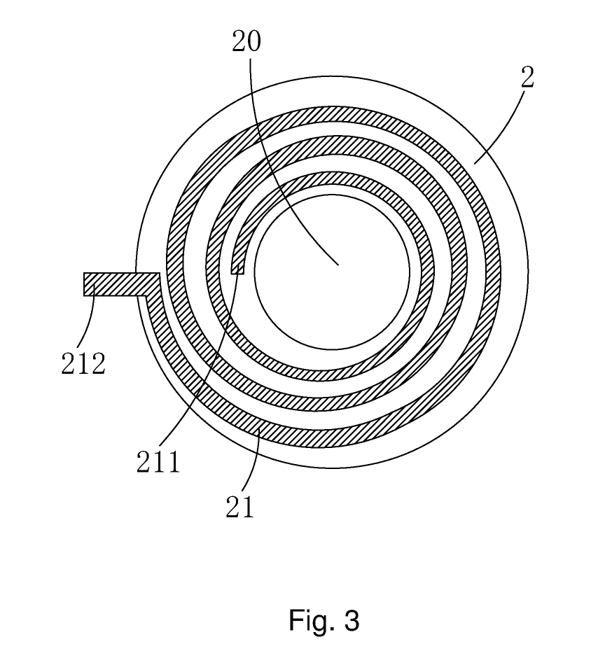

Referring to FIGS. 2-4, the present invention provides a vacuum deposition heating device, which comprises a heating device outer wall 3, a crucible 1 disposed inside the heating device outer wall 3, and a crucible cover 2 positioned on the crucible 1.

Specifically, a primary heating coil 11 is arranged between the crucible 1 and the heating device outer wall 3 and corresponds to outer circumferences of the crucible 1 and the crucible cover 2. The crucible cover 2 has a center in which a jet opening 20 that extends through top and bottom surfaces of the crucible cover 2 is formed to allow, in a vacuum deposition process, vaporized deposition material molecules to jet out of jet opening 20 and get deposited on a substrate to form a solid state film. The crucible cover 2 is provided thereon with a secondary heating coil 21 corresponding to an outer circumference of the jet opening 20. The primary heating coil 11 and the secondary heating coil 21 are electrically connected to a power supply and can be controlled individually and independently for heating so that control of temperature distribution of the crucible 2 in both a vertical axial direction and a horizontal radial direction can be achieved simultaneously, whereby a temperature difference in the horizontal radial direction of the crucible can be effectively reduce, while a temperature gradient is maintained from top to bottom of the crucible to effectively prevent opening jamming.

Specifically, the secondary heating coil 21 is of a helical form, comprising a tailing end 211 located at a terminal of an innermost turn and an electrode end 212 located at a terminal of an outermost turn. The tailing end 211 is positioned on the crucible cover 2 and the electrode end 212 projects outside the crucible cover 2 and partially extends downward in a vertical direction.

Specifically, an electrical connector 22 is arranged between the crucible 1 and the heating device outer wall 3 at a location corresponding to a lower tip of the electrode end 212. The electrode end 212 is partly inserted into the electrical connector 22. The electrical connector 22 is electrically connected to a heating circuit 23. The electrical connector 22 can be in the form of a socket for easy insertion and withdrawal, whereby during a vacuum deposition process, the secondary heating coil 21 can be conveniently removed for changing the material disposed in the crucible. Once the crucible is re-installed, the secondary heating coil 21 can be conveniently re-mounted.

Specifically, a heating device base 24 is arranged under the crucible 1.

Specifically, the primary heating coil 11 has a coil distribution density that is arranged in an upper portion of the crucible 1 and is greater than a coil distribution density thereof arranged in a lower portion of the crucible 1 so that the upper portion of the crucible 2 is provided with a temperature that is slightly higher than that of the lower portion. This effectively handles the issue that the crucible 2 needs to have a temperature difference in the vertical axial direction and a temperature gradient from top to bottom is present in the crucible 2 thereby effectively preventing opening jamming and maintaining stable deposition conditions.

Specifically, in a vacuum deposition process, application of electricity to the primary heating coil 11 and the secondary heating coil 21 can be controlled individually such that the temperature of the crucible cover 2 is higher than the temperature of the crucible 1 thereby effectively reducing a temperature difference of the crucible 2 in the horizontal radial direction to further prevent opening jamming and better maintain stable deposition conditions.

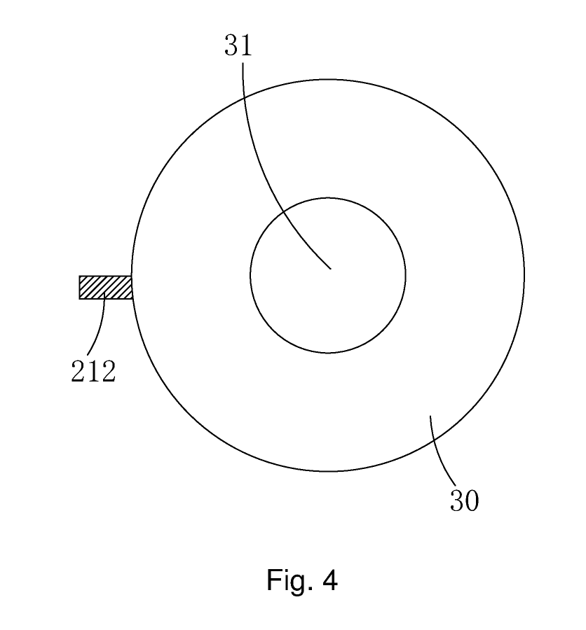

As shown in FIG. 4, the secondary heating coil 21 is provided with a protective cover 30 to provide protection to the secondary heating coil 21 and prevent deformation thereof. The protective cover 30 has a shape and a size respectively corresponding to a shape and a size of the secondary heating coil 21 in order to house and receive the secondary heating coil 21 therein. Further, the protective cover 30 has a center in which a hole 31 is formed and corresponds to the jet opening 20. The hole 31 has a size substantially equal to or greater than a size of the jet opening 20.

Specifically, the protective cover 30 is made of metal, such as titanium, aluminum, and stainless steel.

Specifically, the protective cover 30 can be fixed, through welding, to the secondary heating coil 21; or alternatively, the protective cover 30 is provided with a retention slot and the secondary heating coil 21 is fit into and retained in the retention slot.

Specifically, the crucible cover 2 is provided with a first thermal couple 25 at a location corresponding to an outer edge of the secondary heating coil 21 to monitor the temperature of the crucible cover 2; and the crucible 1 is provided with a second thermal couple 26 at a location adjacent to a bottom thereof to monitor the temperature of the crucible 1 so as to ensure that the temperature of the crucible cover 2 is slightly higher than the temperature of the crucible 1 and also lower than a decomposition temperature of the material.

In summary, the present invention provides a vacuum deposition heating device, which comprises a primary heating coil arranged around circumferences of a crucible and a crucible cover and a secondary heating coil arranged on the crucible cover, wherein the primary heating coil and the secondary heating coil are controllable independently for heating so as to ensure a temperature from top to bottom present in the crucible and at the same time effectively reducing a temperature difference in the crucible in a horizontal radial direction to prevent opening jamming and allow for expansion of diameter to thereby increase the amount of material applied, reduce the times of chamber opening, increase manufacturing efficiency. In addition, the structure is simple and the manufacture thereof is easy.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A vacuum deposition heating device, comprising a heating device outer wall, a crucible disposed inside the heating device outer wall, and a crucible cover positioned on the crucible;
a primary heating coil being arranged between the crucible and the heating device outer wall and corresponding to outer circumferences of the crucible and the crucible cover; the crucible cover having a center in which a jet opening that extends through top and bottom surfaces of the crucible cover is formed, the crucible cover being provided thereon with a secondary heating coil corresponding to an outer circumference of the jet opening; the primary heating coil and the secondary heating coil being electrically connected to a power supply and being independently controllable for heating.

2. The vacuum deposition heating device as claimed in claim 1, wherein the secondary heating coil is of a helical form, comprising a tailing end located at a terminal of an innermost turn and an electrode end located at a terminal of an outermost turn; the tailing end is positioned on the crucible cover; and the electrode end projects outside the crucible cover and partially extends downward in a vertical direction.

3. The vacuum deposition heating device as claimed in claim 2, wherein an electrical connector is arranged between the crucible and the heating device outer wall at a location corresponding to a lower tip of the electrode end; the electrode end is inserted into the electrical connector; and the electrical connector is electrically connected to a heating circuit.

4. The vacuum deposition heating device as claimed in claim 1, wherein the primary heating coil has a coil distribution density arranged in an upper portion of the crucible and greater than a coil distribution density arranged in a lower portion of the crucible.

5. The vacuum deposition heating device as claimed in claim 1, wherein in a vacuum deposition process, application of electricity to the primary heating coil and the secondary heating coil is controlled individually so as to have a temperature of the crucible cover higher than a temperature of the crucible.

6. The vacuum deposition heating device as claimed in claim 1, wherein the secondary heating coil is provided with a protective cover.

7. The vacuum deposition heating device as claimed in claim 6, wherein the protective cover is made of a metal.

8. The vacuum deposition heating device as claimed in claim 7, wherein the protective cover and the secondary heating coil are welded together; or alternatively, the protective cover is provided with a retention slot and the secondary heating coil is fit into and retained in the retention slot.

9. The vacuum deposition heating device as claimed in claim 1, wherein the crucible cover is provided with a first thermal couple at a location corresponding to an outer edge of the secondary heating coil to monitor a temperature of the crucible cover; and the crucible is provided with a second thermal couple at a location adjacent to a bottom thereof to monitor a temperature of the crucible.

10. A vacuum deposition heating device, comprising a heating device outer wall, a crucible disposed inside the heating device outer wall, and a crucible cover positioned on the crucible;
a primary heating coil being arranged between the crucible and the heating device outer wall and corresponding to outer circumferences of the crucible and the crucible cover; the crucible cover having a center in which a jet opening that extends through top and bottom surfaces of the crucible cover is formed, the crucible cover being provided thereon with a secondary heating coil corresponding to an outer circumference of the jet opening; the primary heating coil and the secondary heating coil being electrically connected to a power supply and being independently controllable for heating;
wherein the secondary heating coil is of a helical form, comprising a tailing end located at a terminal of an innermost turn and an electrode end located at a terminal of an outermost turn; the tailing end is positioned on the crucible cover; and the electrode end projects outside the crucible cover and partially extends downward in a vertical direction;
wherein the primary heating coil has a coil distribution density arranged in an upper portion of the crucible and greater than a coil distribution density arranged in a lower portion of the crucible;
wherein in a vacuum deposition process, application of electricity to the primary heating coil and the secondary heating coil is controlled individually so as to have a temperature of the crucible cover higher than a temperature of the crucible.

11. The vacuum deposition heating device as claimed in claim 10, wherein an electrical connector is arranged between the crucible and the heating device outer wall at a location corresponding to a lower tip of the electrode end; the electrode end is inserted into the electrical connector; and the electrical connector is electrically connected to a heating circuit.

12. The vacuum deposition heating device as claimed in claim 10, wherein the secondary heating coil is provided with a protective cover.

13. The vacuum deposition heating device as claimed in claim 12, wherein the protective cover is made of a metal.

14. The vacuum deposition heating device as claimed in claim 13, wherein the protective cover and the secondary heating coil are welded together; or alternatively, the protective cover is provided with a retention slot and the secondary heating coil is fit into and retained in the retention slot.

15. The vacuum deposition heating device as claimed in claim 10, wherein the crucible cover is provided with a first thermal couple at a location corresponding to an outer edge of the secondary heating coil to monitor a temperature of the crucible cover; and the crucible is provided with a second thermal couple at a location adjacent to a bottom thereof to monitor a temperature of the crucible.
